(19) United States
(12) Patent Application Publication
(10) Pub. No.: US 2023/0170390 A1
(43) Pub. Date: Jun. 1, 2023

(54) SIC-BASED ELECTRONIC DEVICE WITH ENHANCED ROBUSTNESS, AND METHOD FOR MANUFACTURING THE ELECTRONIC DEVICE

(71) Applicant: STMICROELECTRONICS S.r.l., Agrate Brianza (IT)

(72) Inventors: Simone RASCUNA', Catania (IT); Valeria PUGLISI, Catania (IT); Gabriele BELLOCCHI, Catania (IT)

(73) Assignee: STMICROELECTRONICS S.r.l., Agrate Brianza (IT)

(21) Appl. No.: 17/941,788

(22) Filed: Sep. 9, 2022

(30) Foreign Application Priority Data
Nov. 26, 2021 (IT) 102021000029969

(51) Int. Cl. H01L 29/16; H01L 29/872; H01L 29/20

(52) U.S. Cl. CPC H01L 29/1608; H01L 29/872; H01L 29/2003

(57) ABSTRACT

An electronic device comprising: a semiconductor body of silicon carbide; a first insulating layer on a first surface of the semiconductor body, of a first material with electrical-insulator or dielectric characteristics; a first layer of metal material extending in part on the first surface of the semiconductor body and in part on the first insulating layer; an interface layer on the first layer of metal material and on the first insulating layer, of a second material different from the first material; and a passivation layer of the first material on the interface layer. The first material is silicon oxide, and the second material is silicon nitride.

### BACKGROUND

### Technical Field

The present disclosure relates to an electronic device and to a method for manufacturing the electronic device. In particular, the electronic device is a SIC-based device and has enhanced robustness.

### Description of the Related Art

The semiconductor industry has been showing considerable interest in silicon carbide (SiC), in particular for the manufacture of electronic components such as diodes or transistor, above all for power applications.

The electronic devices formed in a silicon-carbide substrate, in its different polytypes (for example, 3C-SiC, 4H-SiC, 6H-SiC), have numerous advantages such as low on-state output resistance, low leakage current, resistance to high operating temperatures and high operating frequencies.

However, the development and manufacture of SiC-based electronic devices are limited by factors such as the electrical and mechanical properties of passivation layers (comprised in these electronic devices and, for example, extending over semiconductor bodies of SiC of the electronic devices). In particular, it is known to obtain the passivation layers by using polymeric materials (e.g., polyimide) that make it possible to withstand high operating temperatures of the electronic devices and present high dielectric strength, for example higher than 400 kV/mm. In detail, the high dielectric strength of the polymeric materials guarantees that the passivation layers withstand high electrical fields, and consequently high differences of potential across them, without undergoing electrical breakdown, and therefore without becoming electrically conductive.

However, polymeric materials have high coefficients of thermal expansion (CTE) (e.g., CTE=43e⁻⁶ 1/K for the material polybenzobisoxazole, or PIX), and this causes problems of adhesion of the SiC passivation layer, which presents a lower coefficient of thermal expansion (CTE=3.8e⁻⁶ 1/K).

In particular, these problems of adhesion between the passivation layer and the SiC may arise during thermal cycling tests (conducted, for example, between approximately −50° C. and approximately +150° C.) or during use of the electronic device, when the latter is subjected to high thermal swings (e.g., it is subjected to differences of operating temperature equal to, or higher than, approximately 200° C.). On account of the large difference in CTE between the passivation layer and the SiC, these high thermal swings generate mechanical stresses at an interface between the passivation layer and the SiC, which can lead to (at least partial) delamination of the passivation layer with respect to the SiC semiconductor body.

In the case where this delamination were to be sufficiently extensive (e.g., such that no portion of the passivation layer is interposed between two metallizations of the electronic device set at different potentials, which are therefore separated from one another only by air), electrical discharges may be generated at said interface, leading to damage of the electronic device itself. In particular, the risk of damage of the electronic device increases when the latter is used in reverse-biasing conditions, on account of the high voltage difference (e.g., higher than 1000 V) to be withstood.

Known solutions to this problem comprise the use of a plurality of dielectric layers of materials different from one another (e.g., silicon nitride, silicon oxide and polyimide in succession to one another) to form a passivation multilayer designed to limit the mechanical stresses at the interface with the SiC semiconductor body.

### BRIEF SUMMARY

According to the present disclosure, an electronic device and a method for manufacturing the electronic device are provided.

### BRIEF DESCRIPTION OF THE SEVERAL VIEWS OF THE DRAWINGS

For a better understanding of the present disclosure, a preferred embodiment thereof is now described, purely by way of non-limiting example, with reference to the attached drawings, wherein:

FIG. 1 illustrates, in a cross-sectional view, an electronic device of a known type;

FIG. 2 illustrates, in a cross-sectional view, an electronic device according to an embodiment of the present disclosure;

FIGS. 3A-3D show, in cross-sectional views, steps for manufacturing the electronic device of FIG. 2, according to an embodiment of the present disclosure and limitedly to steps useful for understanding the present disclosure; and

FIG. 4 illustrates, in a cross-sectional view, an electronic device according to a further embodiment of the present disclosure.

### DETAILED DESCRIPTION

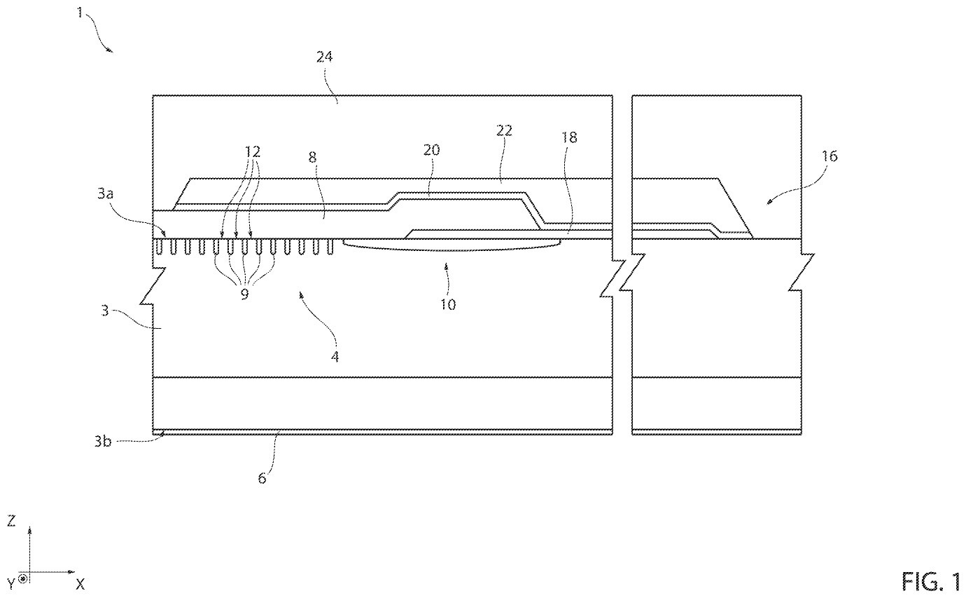

FIG. 1 shows, in lateral cross-sectional view in a (triaxial) cartesian reference system of axes X, Y, Z, a portion of an electronic device (here by way of example a JBS or Junction barrier Schottky diode) 1 of a known type.

The JBS device 1 comprises a semiconductor body 3 of SiC of an N type, provided with a surface 3a opposite to a surface 3b. The semiconductor body includes, for example, a substrate and one or more regions grown epitaxially on the substrate, of an N type and having respective values of doping concentration. The JBS device 1 further comprises multiple junction barrier (JB) elements 9 in the semiconductor body 3, facing the top surface 3a and each including a respective implanted region in the semiconductor body 3, of a P type, and an ohmic contact on the implanted region, at the level of the top surface 3a of the semiconductor body 3. The JBS device 1 further comprises a first metallization 8, which extends over the top surface 3a, in electrical contact with the junction barrier elements 9 through the respective ohmic contacts. The JBS device 1 further comprises an edge-termination region 10 (or protection ring), in particular an implanted region of a P type, which surrounds completely the JB elements 9.

Schottky diodes 12 are formed at the interface between the anode metallization 8 and the semiconductor body 3, where semiconductor-metal Schottky junctions are formed. The region of the MPS device 1 that includes the JB elements 9 and the Schottky diodes 12 (namely, the region contained within the protection ring 10) is an active area 4 of the JBS device 1.

The JBS device 1 further comprises a second metallization 6, which extends over the bottom surface 3b. The first and the second metallizations 8, 6 form, respectively, electrical anode and cathode terminals, which can be biased during use of the JBS device 1.

Extending outside the edge-termination region 10 is an electrically passive region 16.

Extending partially over the edge-termination region 10 is an insulating layer 18, of insulating or dielectric material, in particular silicon oxide (SiO₂).

The first metallization 8 is in electrical contact with a portion of the edge-termination region 10, where the latter is not covered by the insulating layer 18, and likewise extends partially over the insulating layer 18. An interface layer 20, here of silicon nitride (SiN), extends over the first metallization 8 and the insulating layer 18. Furthermore, the JBS device 1 comprises a passivation layer 22, in particular of polyimide, which extends over the interface layer 20. In other words, the interface layer 20 serves as interface between the passivation layer 22 and the underlying layers, here the first metallization 8 and the insulating layer 18. The interface layer 20 may be omitted; however, the present applicant has found that the interface layer 20 improves adhesion of the passivation layer 22 with the underlying layers.

A protection layer 24 of a resin, such as bakelite, extends over the passivation layer 22, protecting the JBS device 1 when inserted in a package (not illustrated).

However, even though the interface layer 20 improves, as has been said, adhesion of the passivation layer 22 with the underlying layers, some critical conditions of use or testing of the JBS device 1 (e.g., thermo-mechanical or thermal stresses) may cause a delamination or partial detachment of the passivation layer 22 from the interface layer 20. This in particular occurs in conditions of stress caused by high temperatures of use (e.g., above 150° C.). This effect, in addition to rendering the JBS device 1 structurally brittle, may be a contributing cause of the occurrence of undesired electrical discharges that affect electrical operation of the JBS device 1. In fact, the applicant has found that phenomena of mechanical stress, for example during assembly, may generate a stress in the interface layer 20 such as to cause local cracks thereof throughout the thickness, which, at the first metal layer 8, are the cause of these electrical discharges. These problems are all the more evident when the electronic device 1 is subjected to high thermal swings and to high voltage differences in reverse-biasing conditions.

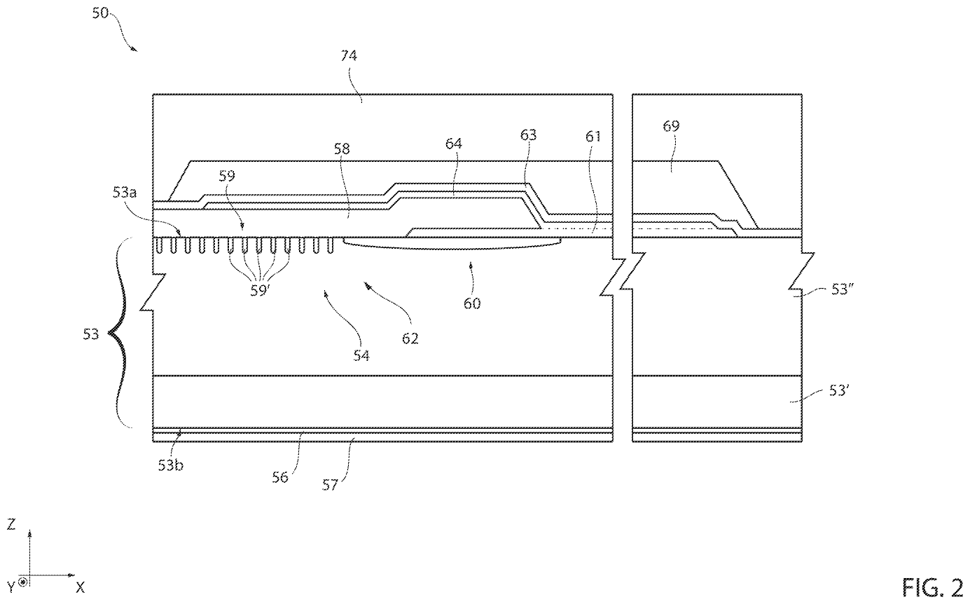

FIG. 2 shows, in lateral cross-sectional view in the same (triaxial) cartesian reference system of axes X, Y, Z as that of FIG. 1, an electronic device 50 according to an aspect of the present disclosure. For example, the device 50 is a JBS diode, however, the present disclosure is not limited to this example device and finds application also in other types of electronic devices, for example power devices, such as MOSFET, IGBT, MPS, Schottky diode, PN diode, PiN diode, etc.

The electronic device 50 comprises the elements described herein, illustrated with reference to FIG. 2.

A semiconductor body 53, e.g., including a substrate and, in some embodiments, one or more epitaxial layers grown thereon, of SiC with a doping of an N or a P type (in what follows a doping of an N type will be used as example), is provided with a surface 53a opposite to a surface 53b in the direction of the axis Z. The semiconductor body 53 includes, in this example, a substrate 53′ on which a drift layer 53″, e.g., an epitaxial layer, has been grown, consisting of SiC of an N type (for example 4H-SiC, however, other polytypes may be used such as, but not exclusively, 2H-SiC, 3C-SiC and 6H-SiC). For instance, the substrate has a concentration of dopants of an N type comprised between 1·10¹⁹ at/cm³ and 1·10²² at/cm³ and has a thickness, measured along the axis Z between the surfaces 53a and 53b, comprised between 300 μm and 450 μm, and for example equal to approximately 360 μm. The drift layer has a respective dopant concentration lower than the dopant concentration of the substrate and a thickness comprised, for example, between 5 and 15 μm.

An ohmic-contact layer 56 (for example, of nickel silicide) extends over the surface 53b of the substrate 53, and a metallization 57, in this example a cathode metallization, for example, of Ti/NiV/Ag or Ti/NiV/Au, extends over the ohmic-contact region 56.

One or more doped regions 59′ of a P type extend in the semiconductor body 53 (for example, in the drift layer), facing (or adjacent to) the top surface 53a; each doped region 59′ houses a respective ohmic contact (not shown for simplicity) such that each doped region 59′ forms a respective junction barrier (JB) element 59. An edge-termination region, or protection ring, 60, for example a further doped region of a P type, extends in the drift layer, faces (or is adjacent to) the top surface 53a, and surrounds completely (in plan view, in a plane XY defined by the axes X and Y) the JB elements 59. In some embodiments, the edge-termination region 60 may be omitted.

An insulating layer 61 (of insulating or dielectric material, i.e., silicon oxide, or TEOS) extends over the top surface 53a so as to surround completely (in view in the plane XY) the JB elements 59 and to partially overlap the protection ring 60 (when present).

A metallization 58, in this example an anode metallization, for example, of Ti/AlSiCu or Ni/AlSiCu, extends over a portion of the top surface 53a delimited on the outside by the insulating layer 61 (i.e., at the JB elements 59/active area 54) and, partially, over the insulating layer 61.

One or more Schottky diodes 62 are formed at the interface between the semiconductor body 53 and the anode metallization 58, alongside the doped regions 59′. For example, (semiconductor-metal) Schottky junctions are formed by portions of the semiconductor layer 53 in direct electrical contact with respective portions of the anode metallization 58.

Furthermore, each ohmic contact extending in the respective doped region 59′ provides an electrical connection having a value of electrical resistivity lower than the value of electrical resistivity of the doped region 59′ that houses it. The JB elements 59 are therefore PiN diodes.

The region of the electronic device 50 that includes the JB elements 59 and the Schottky diodes 62 (i.e., the region delimited by the protection ring 60) is an active area 54 of the electronic device 50.

Present outside the active area 54, i.e., beyond the edge-termination region 60, is a lateral surface 53c of the semiconductor body 53, for example extending substantially orthogonal to the top surface 53a. The lateral surface 53c is formed following upon a step of dicing or singulation of a SiC wafer in which a plurality of electronic devices 50 are obtained. The dicing step has the function of separating one electronic device 50 from another device 50 of the same wafer. Dicing takes place at a scribe line (not shown) of the SiC wafer from which the electronic device 50 is obtained; this scribe line surrounds at a distance, in the plane XY, the active region 54, the protection ring 60, and the insulating layer 61.

A protection layer 74, of a resin, such as, for example, bakelite, extends over the passivation layer 69, protecting the electronic device 50 when inserted in a package (not illustrated).

A further insulating layer 64, for example of a dielectric or insulating material (for example, the same material as the one used for the insulating layer 61, such as silicon oxide or TEOS) extends over the anode metallization 58 and a portion of the insulating layer 61 that is exposed from and alongside the anode metallization 58.

The insulating layer 61 has, for example, a thickness, along the axis Z, comprised between 0.5 and 2 μm; the insulating layer 64 has, for example, a thickness, along the axis Z, comprised between 0.5 and 2 μm.

An interface layer 63, here of silicon nitride (SiN), extends over the insulating layer 64.

A passivation layer 69 extends on the interface layer 63. The interface layer 63 serves as interface between the passivation layer 69 and the underlying layers, here the insulating layer 64.

According to an aspect of the present disclosure, the passivation layer 69 is of insulating or dielectric material, for example the same material as that of the insulating layer 64. In this way, any possible thermal stresses to which the device 50 is subjected during use or during testing steps do not have a significant impact, in terms of stress, on the interface layer 63, which is therefore less subject to cracking. The passivation layer 69 is, for example, of silicon oxide or TEOS.

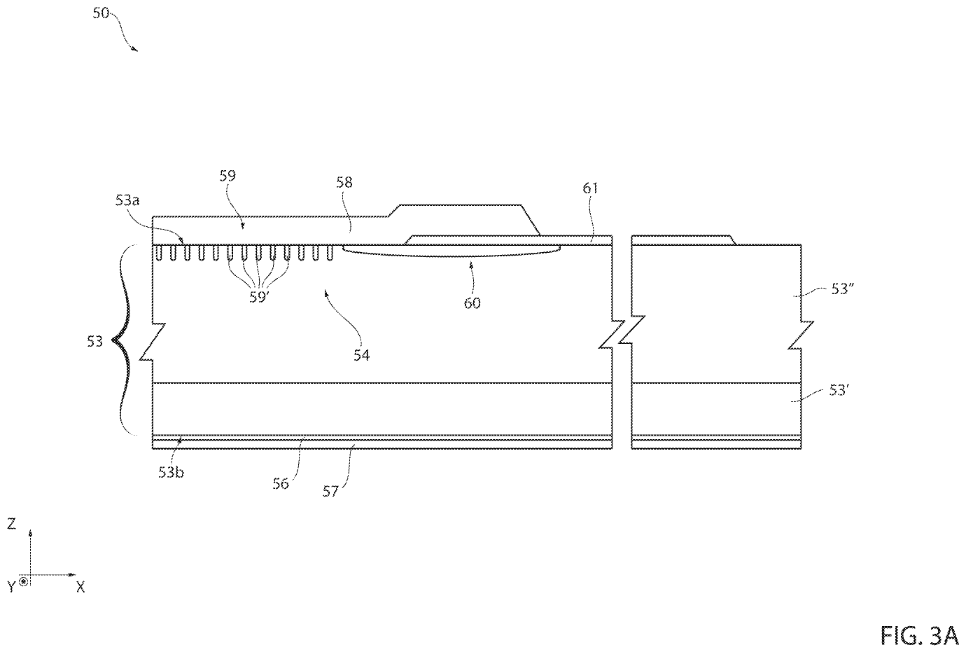

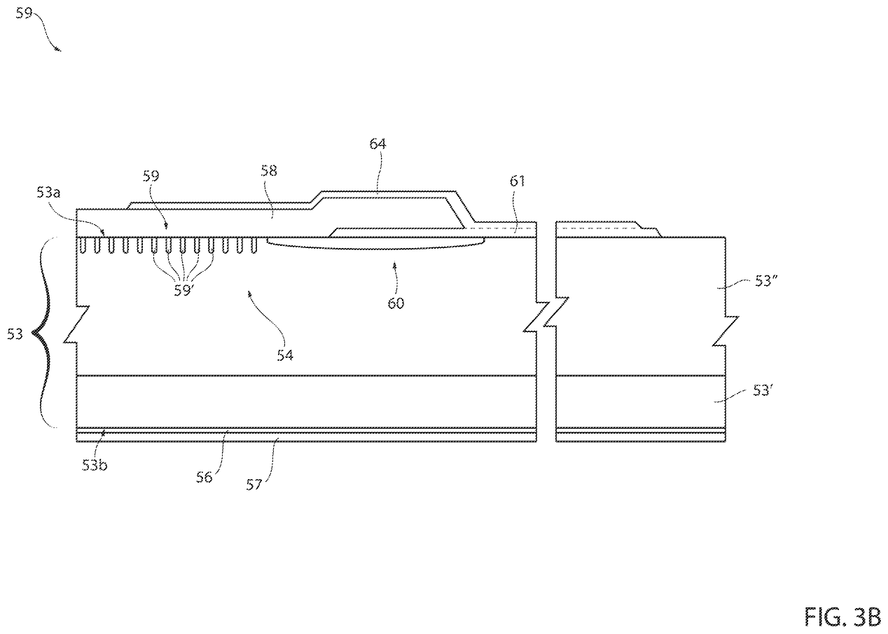

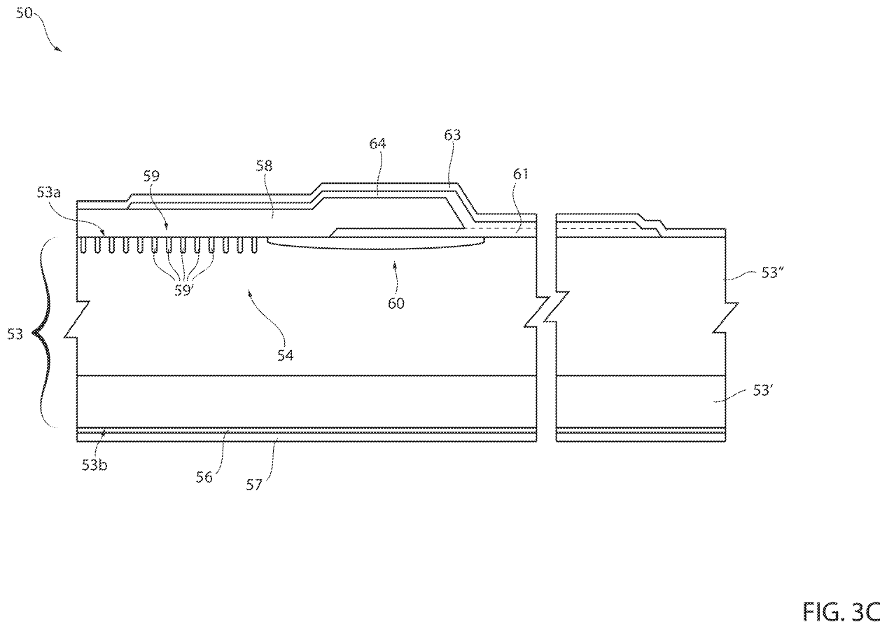

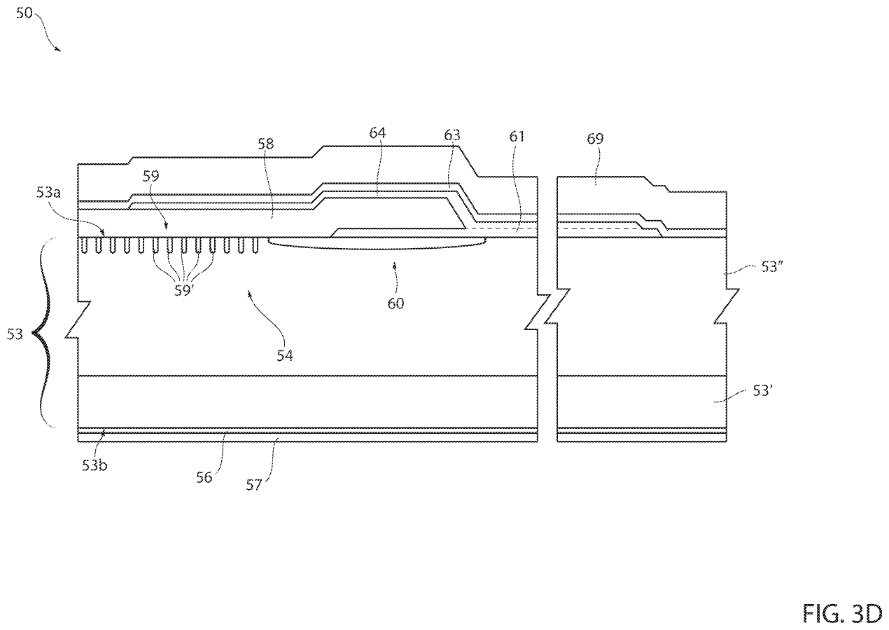

Steps for manufacture of the electronic device 50 of FIG. 2 are described in what follows with reference to FIGS. 3A-3D and limitedly to manufacturing steps useful for understanding the present disclosure. FIGS. 3A-3D are represented in the same triaxial system as that of FIG. 2.

With reference to FIG. 3A, a wafer is provided that includes the SiC semiconductor body 53, following upon manufacturing steps that are designed to form elements of the electronic device 50 described previously (and not discussed here any further) and identified by the same reference numbers.

With reference to FIG. 3A, after formation of the insulating layer 61 and of the anode metallization 58, a step is carried out of deposition of insulating or dielectric material to form the insulating layer 64. This step is carried out, for example, by a CVD or LPCVD process. The insulating layer 64 is formed on the entire surface of the wafer and for example completely covers the anode metallization 58 and the insulating layer 61.

Then, FIG. 3B, after formation of the insulating layer 64, the interface layer 63 is formed, for example, by deposition of a CVD type of silicon nitride. The interface layer 63 is formed on the entire surface of the wafer and for example covers completely the insulating layer 64.

Then, FIG. 3C, the passivation layer 69 is formed. This step envisages deposition of insulating material, for example silicon oxide or TEOS deposited using the CVD or LPCVD technique. The passivation layer 69 has a thickness chosen, for example, in the range between 1 and 10 μm.

The passivation layer 69 covers the interface layer 63 completely and can be patterned (for example, by lithographic and etching steps) according to the need.

The manufacturing process then continues with subsequent steps to form the further elements of the electronic device 50, not described in detail here (for example, the ohmic-contact layer 56 and the cathode metallization 57).

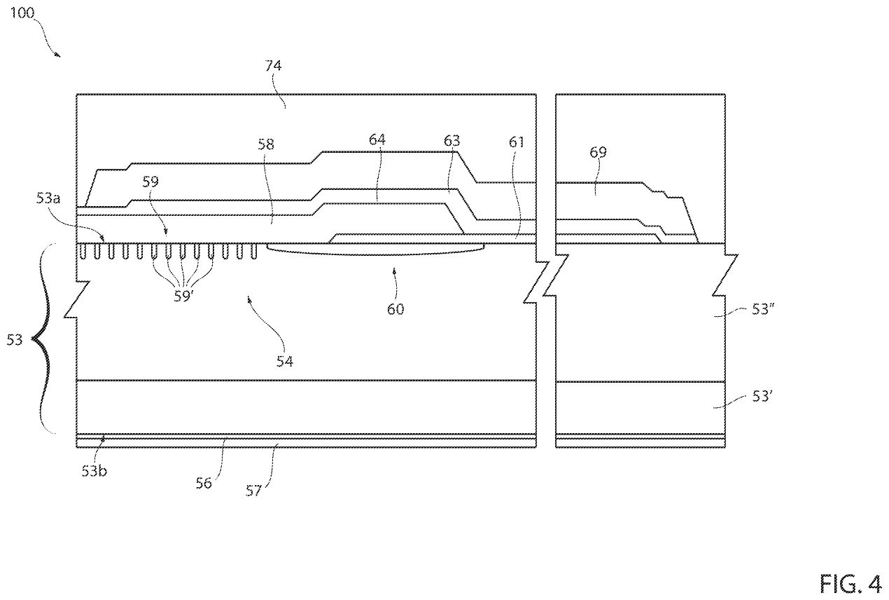

FIG. 4 illustrates an electronic device 100 according to a further embodiment of the present disclosure. The electronic device 100 is represented in the same (triaxial) cartesian reference system of axes X, Y, Z as those of FIGS. 1 and 2. For example, the electronic device 100 is a JBS diode, similar to what has been described with reference to FIGS. 1 and 2; however, also in this case, the present disclosure is not limited to a JBS device and finds application also in other types of electronic devices, for example power devices, such as MOSFET, IGBT, MPS, Schottky diode, PN diode, PiN diode, etc.

Elements of the electronic device 100 common to the electronic device 50 of FIG. 2 are designated by the same reference numbers and will not be described any further.

For example, the electronic device 100 does not comprise the insulating layer 64. Therefore, in this embodiment, the interface layer 63 extends directly on, and in contact with, the anode metallization 58 and with the insulating layer 61.

The passivation layer 69, of the type already described previously, extends over the interface layer 63 and is physically separated from the anode metallization 58 and from the insulating layer 61 by the interface layer 63. The steps for manufacturing the electronic device 100 are similar to those described with reference to FIGS. 3A-3D, with the exception of the step regarding formation of the insulating layer 64.

From an examination of the characteristics of the present disclosure according to the present disclosure the advantages that it allows to obtain are evident.

For example, the passivation layer obtained according to the present disclosure is particularly robust and reliable during testing of thermal stresses of the electronic device. Furthermore, it reduces propagation of stresses that cause cracking of the interface layer 63.

In other words, the present disclosure (which avoids the need to provide the passivation layer 69 of polymeric material), guarantees high electrical performance of the electronic device 50, 100 and, at the same time, eliminates structural problems linked to the possible detachment of the polymeric passivation layer (e.g., following upon thermal cycles or cycles of use of the electronic device 50, 100).

Finally, it is clear that modifications and variations may be made to the present disclosure described and illustrated herein, without thereby departing from the scope of the present disclosure, as defined in the attached claims.

An electronic device (50; 100) may be summarized as including a semiconductor body (53) of silicon carbide; a first insulating layer (61) on a first surface (53a) of the semiconductor body (53), of a first material with electrical-insulator or dielectric characteristics; a first layer of metal material (58) extending in part on the first surface (53a) of the semiconductor body (53) and in part on the first insulating layer (61); an interface layer (63) on the first layer of metal material (58) and on the first insulating layer (61), of a second material different from the first material; and a passivation layer (69) of said first material on the interface layer (63).

The first material may be silicon oxide or TEOS.

The second material may be silicon nitride.

The electronic device may further include a second insulating layer (64) interposed between the interface layer (63) and the underlying first insulating layer (61) and first layer of metal material (58).

The second insulating layer (64) may be of said first material.

The electronic device may further include an active area (54), said first layer of metal material (58) extending at least in part overlapping, and in electrical contact with, the first surface (53a) of the semiconductor body at the active area (54).

The electronic device may further include an edge-termination region (60) surrounding, at least in part, the active area (54), wherein the edge-termination region (60) is a region implanted in the semiconductor body at the first surface (53a) and has an electrical conductivity opposite to that of the semiconductor body (53), the first insulating layer (61) extending on the first surface (53a) at a distance from the active area (54) and at least partially overlapping the edge-termination region (60).

The electronic device may further include a second layer of metal material (57) on a second surface (53b), opposite to the first surface (53a), of the semiconductor body (53), wherein the first layer of metal material (58) and the second layer of metal material (57) form respective electrical-conduction terminals of the electronic device (50; 100).

The electronic device may further include one or more junction barrier diodes (59) and/or Schottky diodes in said active area (54), at the first surface (53a).

The electronic device chosen in the group may include a Schottky diode, a PiN diode, a PN diode, an MPS device, a JBS diode, a MOSFET, an IGBT, a power device.

A method for manufacturing an electronic device (50; 100) may be summarized as including the steps of forming, on a first surface (53a) of a semiconductor body (53) of silicon carbide, a first insulating layer (61) of a first material with electrical-insulator or dielectric characteristics; forming a first layer of metal material (58) in part on the first surface (53a) of the semiconductor body (53) and in part on the first insulating layer (61); forming an interface layer (63) on the first layer of metal material (58) and on the first insulating layer (61), of a second material different from the first material; and forming a passivation layer (69) of said first material on the interface layer (63).

The first material may be silicon oxide or TEOS.

The second material may be silicon nitride.

The manufacturing method may further include the step of forming a second insulating layer (64) on the first insulating layer (61) and on the first layer of metal material (58), and wherein the step of forming the interface layer (63) includes forming the interface layer (63) on the second insulating layer (64).

The second insulating layer (64) may be of said first material.

The manufacturing method may further include the step of forming an active area (54), said first layer of metal material (58) being formed at least in part overlapping, and in electrical contact with, the first surface (53a) of the semiconductor body at the active area (54).

The manufacturing method may further include the step of implanting, in the semiconductor body at the first surface (53a) and surrounding at least in part the active area (54), dopant species having an electrical conductivity opposite to that of the semiconductor body (53), thus forming an edge-termination region (60), the first insulating layer (61) being formed on the first surface (53a) at a distance from the active area (54) and at least partially overlapping the edge-termination region (60).

The manufacturing method may further include the step of forming a second layer of metal material (57) at a second surface (53b), opposite to the first surface (53a), of the semiconductor body (53), wherein the first layer of metal material (58) and the second layer of metal material (57) form respective electrical-conduction terminals of the electronic device (50; 100).

The manufacturing method may further include the step of forming one or more junction barrier diodes (59) and/or Schottky diodes in said active area (54), at the first surface (53a).

Said electronic device may be chosen in the group including: a Schottky diode, a PiN diode, a PN diode, an MPS device, a JBS diode, a MOSFET, an IGBT, a power device.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a semiconductor body of silicon carbide and having a first type of electrical conductivity;
a first insulating layer over a first surface of the semiconductor body, the first insulating layer having a first material with electrical-insulator or dielectric characteristics;
a first metal layer extending in part over the first surface of the semiconductor body and in part over the first insulating layer;
an interface layer of a second material over the first metal layer and over the first insulating layer, the second material different from the first material; and
a passivation layer of the first material on the interface layer.

2. The electronic device according to claim 1, wherein the first material is one or more of silicon oxide or TEOS.

3. The electronic device according to claim 1, wherein the second material is silicon nitride.

4. The electronic device according to claim 1, further comprising a second insulating layer interposed between the interface layer and the first insulating layer and between the interface layer and the first metal layer.

5. The electronic device according to claim 4, wherein the second insulating layer is of the first material.

6. The electronic device according to claim 1, further comprising an active area at the first surface of the semiconductor body, the first metal layer at least in part overlapping, and in electrical contact with, the active area.

7. The electronic device according to claim 6, further comprising an edge-termination region surrounding, at least in part, the active area,
wherein the edge-termination region is a region implanted in the semiconductor body at the first surface and has a second type of electrical conductivity opposite to the first type of electrical conductivity of the semiconductor body, and
the first insulating layer extends over the first surface at a distance from the active area and at least partially overlapping the edge-termination region.

8. The electronic device according to claim 6, further comprising a second metal layer on a second surface, opposite to the first surface, of the semiconductor body, wherein the first metal layer and the second metal layer form respective electrical-conduction terminals of the electronic device.

9. The electronic device according to claim 6, further comprising one or more of a junction barrier diode or a Schottky diode in the active area.

10. The electronic device according to claim 1, further comprising, in the semiconductor body, one or more of: a Schottky diode, a PiN diode, a PN diode, an MPS device, a JBS diode, a MOSFET, an IGBT, or a power device.

11. A method for manufacturing an electronic device, comprising:
forming, over a first surface of a semiconductor body of silicon carbide, a first insulating layer of a first material with electrical-insulator or dielectric characteristics;
forming a first metal layer of a metal material in part over the first surface of the semiconductor body and in part over the first insulating layer;
forming an interface layer of a second material over the first layer of metal material and over the first insulating layer, the second material different from the first material; and
forming a passivation layer of the first material over the interface layer.

12. The method according to claim 11, wherein the first material is one or more of silicon oxide or TEOS.

13. The method according to claim 11, wherein the second material is silicon nitride.

14. The method according to claim 11, further comprising forming a second insulating layer over the first insulating layer and over the first metal layer,
wherein the forming the interface layer includes forming the interface layer over the second insulating layer.

15. The method according to claim 14, wherein the second insulating layer is of the first material.

16. The method according to claim 11, further comprising forming an active area in the semiconductor body adjacent to the first surface, the first metal layer being formed at least in part overlapping, and in electrical contact with, the active area.

17. The method according to claim 16, further comprising forming an edge-termination region by implanting, in the semiconductor body at the first surface and surrounding at least in part the active area, dopant species of an electrical conductivity type opposite to that of the semiconductor body,
wherein the first insulating layer is formed on the first surface at a distance from the active area and at least partially overlapping the edge-termination region.

18. The method according to claim 16, further comprising forming a metal second layer of a 63 metal material at a second surface of the semiconductor body opposite to the first surface.

19. An electronic device, comprising:
a semiconductor body of silicon carbide and having an active area at a first surface of the semiconductor body;
a first insulating layer of a first dielectric material over the first surface of the semiconductor body;
a first metal layer of a metal material extending in part over the active area and in part over the first insulating layer;
an interface layer of a second dielectric material over the first metal layer and over the first insulating layer; and
a passivation layer of the first dielectric material over the interface layer, the interface layer extending beyond the passivation layer.

20. The device of claim 19, comprising a protection layer over the passivation layer and the interface layer.
